(19) United States
(12) Patent Application Publication
(10) Pub. No.: US 2009/0168292 A1
(43) Pub. Date: Jul. 2, 2009

(54) ELECTROSTATIC CHUCK AND SUBSTRATE TEMPERATURE ADJUSTING-FIXING DEVICE

(75) Inventors: Naoto Watanabe, Nagano-shi (JP); Tadayoshi Yoshikawa, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/334,961

(22) Filed: Dec. 15, 2008

(30) Foreign Application Priority Data
Dec. 27, 2007 (JP) 2007-337691

(51) Int. Cl. H01L 21/683

(52) U.S. Cl. 361/234

(57) ABSTRACT

There is provided an electrostatic chuck for adsorbing and holding an adsorption object placed on an upper surface of a base body having an electrostatic electrode embedded therein and for filling inert gas of which a pressure is adjusted into a space formed between the upper surface of the base body and a lower surface of the adsorption object, wherein the base body includes a gas discharge portion embedded therein so as to discharge the inert gas to the space and a gas path embedded therein so as to introduce the inert gas into the gas discharge portion while communicating with the gas discharge portion.

### BACKGROUND OF THE INVENTION

The present invention relates to an electrostatic chuck and a substrate temperature adjusting-fixing device, and more particularly, to an electrostatic chuck for adsorbing an adsorption object placed on a base body and a substrate temperature adjusting-fixing device.

In the past, a coating device (for example, a CVD device, a PVD device, and the like) or a plasma etching device used to manufacture a semiconductor unit such as an IC or an LSI has a stage for holding a substrate (specifically, for example, a silicon wafer) within a vacuum treatment chamber with high precision. As such a stage, for example, a substrate temperature adjusting-fixing device having an electrostatic chuck is proposed. The substrate temperature adjusting-fixing device holds a substrate in an adsorption state in terms of the electrostatic chuck and performs a temperature control so that the substrate held in an adsorption state has a predetermined temperature.

FIG. 1 is a cross sectional view showing a simplified example of a substrate temperature adjusting-fixing device 100 according to a conventional art. As shown in FIG. 1, the substrate temperature adjusting-fixing device 100 includes an electrostatic chuck 101, an adhesive layer 105, and a base plate 106. Reference numeral 107 denotes a substrate held by the electrostatic chuck 101 in an adsorption state. The electrostatic chuck 101 includes a base body 102 and an electrostatic electrode 103. The base body 102 is fixed onto the base plate 106 via the adhesive layer 105. The base body 102 is made from ceramics.

The outer edge portion of an upper surface 102a of the base body 102 is provided with an outer peripheral seal ring 102b corresponding to an annular protrusion portion in a top view. On the inside of the outer peripheral seal ring 102b in a top view, a plurality of cylindrical protrusion portions 102c is dotted in a polka-dot pattern in a top view.

The electrostatic electrode 103 is a thin-film electrostatic electrode and is embedded in the base body 102. The electrostatic electrode 103 is connected to a DC power source (not shown) provided in the outside of the substrate temperature adjusting-fixing device 100 and holds the substrate 107 in the upper surfaces of the outer peripheral seal ring 102b and the plurality of protrusion portions 102c in an adsorption state upon being applied with a predetermined voltage. The adsorbing-holding force becomes stronger as the voltage applied to the electrostatic electrode 103 becomes larger.

The base plate 106 is used to support the electrostatic chuck 101. The base plate 106 includes a water path 104, a heater (not shown), an annular gas path 108, and a gas introduction portion 108a for introducing inert gas into the annular gas path 108, and controls a temperature of the substrate 107 via the base body 102. The water path 104 includes a cooling water introduction portion 104a and a cooling water discharge portion 104b formed in the lower portion of the base plate 106. The cooling water introduction portion 104a and the cooling water discharge portion 104b are connected to a cooling water control device (not shown) provided in the outside of the substrate temperature adjusting-fixing device 100.

The cooling water control device (not shown) circulates a cooling water so as to cool the base plate 106 in such a manner that the cooling water is introduced from the cooling water introduction portion 104a into the water path 104 and is discharged from the cooling water discharge portion 104b, thereby cooling the base body 102 via the adhesive layer 105. The heater (not shown) is heated upon being applied with a voltage and heats the base body 102 via the adhesive layer 105.

One end of the gas introduction portion 108a is connected to the annular gas path 108 and the other end is terminated in an opening 108a₁ of a lower surface 106b of the base plate 106. Additionally, the base body 102, the adhesive layer 105, and the base plate 106 are provided with a gas discharge portion 108b formed through the base body 102 and the adhesive layer 105 so as to discharge the inert gas introduced into the annular gas path 108. One end of the gas discharge portion 108b is connected to the annular gas path 108 embedded in the base plate 106 and the other end is terminated in an opening 108b₁ of an upper surface 102a of the base body 102.

The opening 108a₁ of the gas introduction portion 108a is connected to a gas pressure control device (not shown) provided in the outside of the substrate temperature adjusting-fixing device 100. The gas pressure control device (not shown) is capable of changing a pressure of inert gas within a range, for example, 0 to 50 Torr and of introducing the inert gas from the opening 108a₁ to the annular gas path 108 via the gas introduction portion 108a.

The inert gas introduced into the annular gas path 108 is discharged to the opening 108b₁ via the gas discharge portion 108b, and is filled into a gas filling portion 109 corresponding to a space formed between the upper surface 102a of the base body 102 and the substrate 107, thereby improving the heat conductivity between the base body 102 and the substrate 107. The outer peripheral seal ring 102b is provided to prevent the inert gas filled in the gas filling portion 109 from leaking to the outside of the gas filling portion 109.

The annular gas path 108 embedded in the base plate 106 will be described in more detail with reference to FIG. 2. FIG. 2 is a schematic top view showing a schematic path of the annular gas path 108. In the same drawing, the same reference numerals are given to the same components as those of FIG. 1, and the description thereof will be omitted. Additionally, since FIG. 1 simply shows the substrate temperature adjusting-fixing device 100, some parts shown in FIG. 1 may not be identical with those shown in FIG. 2. In FIG. 2, the annular gas path 108 is embedded in the base plate 106 and has a structure in which three types of large, middle, and small concentric annular portions are connected to one another at a plurality of positions in a top view. The annular gas path 108 is formed so as to be substantially in parallel to the lower surface 106b of the base plate 106.

The gas introduction portion 108a is formed from the annular gas path 108 toward the lower surface 106b of the base plate 106 and is terminated in the opening 108a₁ of the lower surface 106b of the base plate 106 while communicating with the annular gas path 108. In FIG. 2, the opening 108a₁ is provided at only one position of the lower surface 106b of the base plate 106.

A plurality of the gas discharge portions 108b is formed from the annular gas path 108 toward the upper surface 102a of the base body 102 and is terminated in a plurality of the openings 108b₁ of the upper surface 102a of the base body 102 while communicating with the annular gas path 108. In FIG. 2, the openings 108b₁ are provided at twenty seven positions corresponding to the gas filling portions 109 of the upper surface 102a of the base body 102.

Additionally, an electron beam welding or the like is used to form the water path 104 and the annular gas path 108 in the base plate 106. The electron beam welding is a method in which a filament (cathode) is heated in a high vacuum, emitted electrons are accelerated in a high voltage, the accelerated electrons are collected by an electromagnetic coil, the collected electrons collide with a welding object, and a kinetic energy is converted into a thermal energy to thereby perform a welding.

Likewise, the substrate temperature adjusting-fixing device 100 according to a conventional art holds the substrate 107 in the upper surfaces of the plurality of protrusion portions 102c and the outer peripheral seal ring 102b formed in the upper surface 102a of the base body 102 of the electrostatic chuck 101 in an adsorption state and controls the temperature of the substrate 107 in terms of the water path 104 or the heater (not shown) embedded in the base plate 106, the inert gas being introduced into the annular gas path 108 provided in the base plate 106 to be filled into the gas filling portion 109, thereby improving the heat conductivity between the base body 102 and the substrate 107 to realize a temperature uniformity of the substrate 107 (for example, see Patent Document 1).

Additionally, as another method of making uniform the temperature of the substrate 107, there is proposed a method of forming a plurality of gas paths having different channels (for example, see Patent Document 2) or a method of forming a slit among electrode blocks (for example, see Patent Document 3).

In recent years, it is required to carefully manage the temperature of the substrate 107 held by the electrostatic chuck 101 in an adsorption state in accordance with a high integration of a semiconductor device. In order to realize the careful temperature management of the substrate 107, it is necessary to carefully control a flow rate of the cooling water introduced into the water path 104 or a pressure of the inert gas introduced into the annular gas path 108. For this reason, the paths of the water path 104 and the annular gas path 108 tend to be more complex.

### [Patent Document 1] JP-A-2000-317761

### [Patent Document 2] JP-A-2005-45207

### [Patent Document 3] JP-A-2003-243371

However, in the substrate temperature adjusting-fixing device 100 according to the conventional art, since all of the water path 104 and the annular gas path 108 are provided in the inside of the base plate 106, the structure of the base plate 106 becomes complex. Additionally, since the electron beam welding or the like is used for a treatment, the base plate 106 becomes expensive, thereby causing a problem in that a manufacture cost of the substrate temperature adjusting-fixing device 100 increases.

Additionally, since all of the water path 104 and the annular gas path 108 are provided in the inside of the base plate 106, the temperature of the inert gas introduced into the annular gas path 108 is influenced by the temperature of the base plate 106, thereby causing a problem in that the temperature uniformity of the substrate 107 is disturbed.

### SUMMARY OF THE INVENTION

The present invention is contrived in consideration of the above-described problems, and an object of the invention is to provide an electrostatic chuck and a substrate temperature adjusting-fixing device capable of realizing a decrease in manufacture cost and a temperature uniformity of an adsorption object without being influenced by a temperature of a base plate.

In order to achieve the above-described object, according to a first aspect of the invention, there is provided an electrostatic chuck including:

a base body, and

an electrostatic electrode embedded in the base body, wherein

an adsorption object is placed on an upper surface of a base body,

an inert gas of which a pressure is adjusted is filled into a space formed between the upper surface of the base body and a lower surface of the adsorption object,

the base body is provided with a gas discharge portion embedded therein for discharging the inert gas to the space and a gas path embedded therein, communicating with the gas discharge portion, for introducing the inert gas to the gas discharge portion.

According to a second aspect of the invention, there is provided the electrostatic chuck according to the first aspect, wherein

the gas path is formed into an annular shape in a top view and has a structure in which a plurality of annular portions are connected to one another at a plurality of positions in a top view.

According to a third aspect of the invention, there is provided the electrostatic chuck according to the first or second aspect, wherein

an inner wall of the gas path is provided with a layer formed of a conductive material.

According to a forth aspect of the invention, there is provided the electrostatic chuck according to any one of the first to third aspects, wherein

upper, lower, left, and right portions of the gas path are provided with a layer formed of a conductive material.

According to a fifth aspect of the invention, there is provided the electrostatic chuck according to any one of the first to forth aspects, wherein

the base body includes two or more regions having different volume resistance rates, and

the gas path is provided in the region having the lowest volume resistance rate.

According to a sixth aspect of the invention, there is provided the electrostatic chuck according to the fifth aspect, wherein

the volume resistance rate of the region provided with the gas path is not more than 10¹⁰ Ωm.

According to a seventh aspect of the invention, there is provided a substrate temperature adjusting-fixing device including:

the electrostatic chuck according to any one of the first to sixth aspects, and

a base plate for supporting the electrostatic chuck.

According to an eighth aspect of the invention, there is provided the substrate temperature adjusting-fixing device according to the seventh aspect, wherein

the base plate includes a gas introduction portion embedded therein to introduce the inert gas into the gas path embedded in the base body of the electrostatic chuck.

According to a ninth aspect of the invention, there is provided the substrate temperature adjusting-fixing device according to the eighth aspect, wherein

the base plate further includes:

a heater embedded therein to heat the electrostatic chuck, and

a water path embedded therein to cool the electrostatic chuck.

According to the invention, it is possible to provide an electrostatic chuck and a substrate temperature adjusting-fixing device capable of realizing a decrease in manufacture cost and a temperature uniformity of an adsorption object without being influenced by a temperature of a base plate.

### BRIEF DESCRIPTION OF THE DRAWINGS

FIG. 1 is a cross sectional view showing a simplified example of a substrate temperature adjusting-fixing device 100 according to a conventional art.

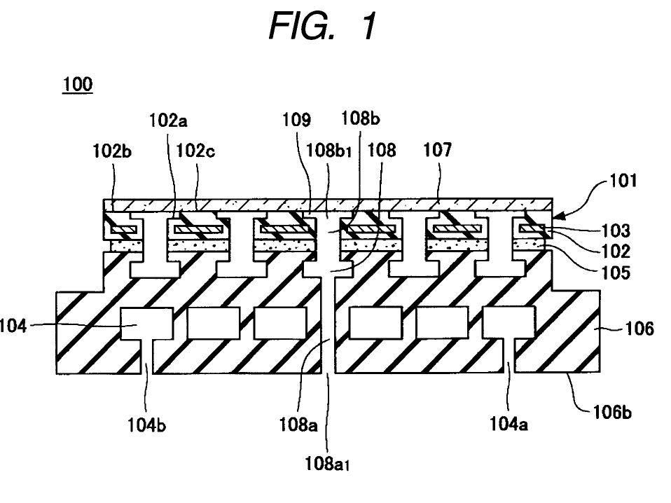

FIG. 2 is a schematic top view showing a schematic path of an annular gas path 108.

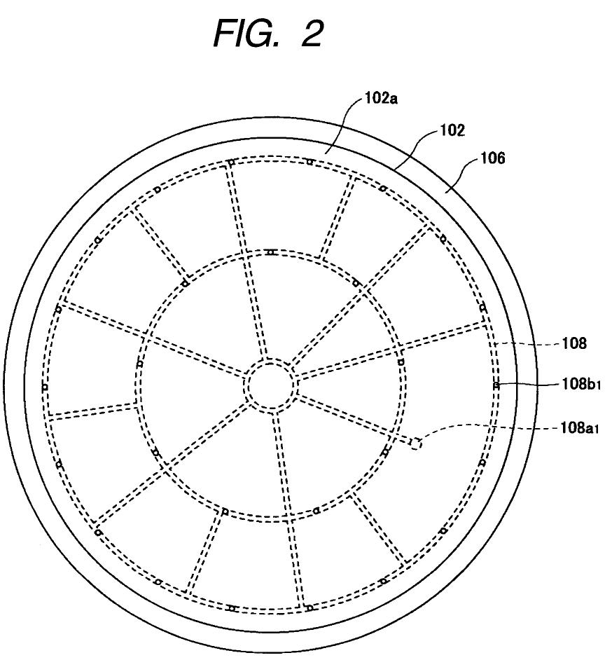

FIG. 3 is a cross sectional view showing a simplified example of a substrate temperature adjusting-fixing device 10 according to a first embodiment of the invention.

FIG. 4 is a schematic top view showing a schematic path of an annular gas path 18.

FIGS. 5(a) and 5(b) are schematic tops view showing a gas path pattern in each layer of a base body 12.

FIG. 6 is a cross sectional view showing a simplified example of a substrate temperature adjusting-fixing device 20 according to a second embodiment of the invention.

FIG. 7 is a cross sectional view showing a simplified example of a substrate temperature adjusting-fixing device 30 according to a third embodiment of the invention.

FIG. 8 is a cross sectional view showing a simplified example of a substrate temperature adjusting-fixing device 40 according to a fourth embodiment of the invention.

FIG. 9 is a cross sectional view showing a simplified example of a substrate temperature adjusting-fixing device 50 according to a fifth embodiment of the invention.

### DETAILED DESCRIPTION OF THE PREFERRED EMBODIMENTS

Hereinafter, exemplary embodiments of the invention will be described with reference to the accompanying drawings.

### First Embodiment

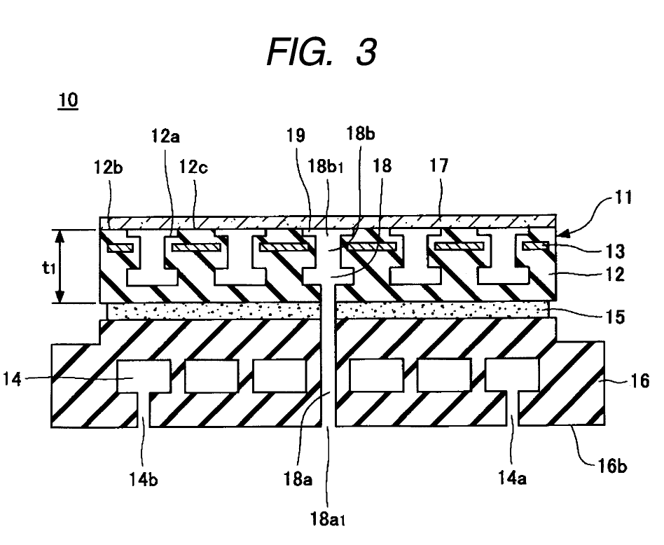

FIG. 3 is a cross sectional view showing a simplified example of a substrate temperature adjusting-fixing device 10 according to a first embodiment of the invention. As shown in FIG. 3, the substrate temperature adjusting-fixing device 10 includes an electrostatic chuck 11, an adhesive layer 15, and a base plate 16. Reference numeral 17 denotes a substrate which is held by the electrostatic chuck 11 in an adsorption state. The substrate 17 is, for example, a silicon wafer or the like.

The electrostatic chuck 11 is a coulombic-force electrostatic chuck having a base body 12 and an electrostatic electrode 13. The base body 12 is a dielectric and is fixed onto the base plate 16 via the adhesive layer 15. As the base body 12, for example, ceramics mainly composed of Al₂O₃ or AlN may be used.

A thickness t₁ of the base body 12 is, for example, 2 mm or more, a specific permittivity (1 KHz) of the base body 12 is for example, in the range of 9 to 10, and a volume resistance rate of the base body 12 is, for example, in the range of 10¹² to 10¹⁶ Ωm. The base body 12 is made in such a manner that n layers of green sheets 121₁ to 121ₙ are laminated, burned, and sintered. Additionally, the green sheet is made, for example, in such a manner that ceramic powder is mixed with a binder, a solvent, and the like to be thereby formed into a sheet shape.

The outer edge portion of an upper surface 12a of the base body 12 is provided with an outer peripheral seal ring 12b corresponding to an annular protrusion portion in a top view. On the inside of the outer peripheral seal ring 12b in a top view, a plurality of cylindrical protrusion portions 12c is dotted in a polka-dot pattern in a top view. The height of the outer peripheral seal ring 12b is the same as those of the plurality of protrusion portions 12c. Each protrusion portion 12c may be formed into a polygonal shape such as a hexagonal shape in a top view or may be formed into a shape in which a plurality of cylinders having different diameters is combined with each other, instead of the cylindrical shape. The substrate 17 is held in the upper surfaces of the outer peripheral seal ring 12b and the plurality of protrusion portions 12c in an adsorption state.

Each protrusion portion 12c is formed by, for example, sandblasting. Specifically, a portion where the protrusion portion 12c needs to be formed in the upper surface 12a of the base body 12 is subjected to masking, minute particles are implanted into the upper surface 12a of the base body 12 in terms of a gas pressure, and then a portion not being subjected to the masking is cut. Additionally, the protrusion portions 12c may be arranged in accordance with any regularity so long as the protrusion portions 12c are uniformly provided in the upper surface 12a of the base body 12.

The inside of the base body 12 is provided with an annular gas path 18 and a gas discharge portion 18b for discharging inert gas introduced into the annular gas path 18. One end of the gas discharge portion 18b is connected to the annular gas path 18, and the other end is terminated in an opening 18b₁ of the upper surface 12a of the base body 12. A gas introduction portion 18a is formed in a part of the base body 12, the adhesive layer 15, and the base plate 16 so as to be formed through the adhesive layer 15 and the base plate 16 and to introduce inert gas into the annular gas path 18 in the base body 12. One end of the gas introduction passage 18a is connected to the annular gas path 18, and the other end is terminated in an opening 18a₁ of a lower surface 16b of the base plate 16.

The opening 18a₁ of the gas introduction portion 18a is connected to a gas pressure control device (not shown) provided in the outside of the substrate temperature adjusting-fixing device 10. The gas pressure control device (not shown) is capable of changing a pressure of inert gas within a range, for example, 0 to 50 Torr and of introducing the inert gas from the opening 18a₁ to the annular gas path 18 via the gas introduction portion 18a.

The inert gas introduced into the annular gas path 18 is discharged to the opening 18b₁ via the gas discharge portion 18b, and is filled in a gas filling portion 19 corresponding to a space formed between the upper surface 12a of the base body 12 and the substrate 17. The inert gas filled in the gas filling portion 19 improves heat conductivity between the base body 12 and the substrate 17, thereby realizing a temperature uniformity of the substrate 17. The outer peripheral seal ring 12b is provided to prevent the inert gas filled in the gas filling portion 19 from leaking to the outside of the gas filling portion 19.

The electrostatic electrode 13 is a thin-film electrode and is embedded in the base body 12. The electrostatic electrode 13 is connected to a DC power source (not shown) provided in the outside of the substrate temperature adjusting-fixing device 10 and holds the substrate 17 in the upper surfaces of the outer peripheral seal ring 12b and the plurality of protrusion portions 12c in an adsorption state upon being applied with a predetermined voltage. The adsorbing-holding force becomes stronger as the voltage applied to the electrostatic electrode 13 becomes larger. The electrostatic electrode 13 may be formed into a unipolar shape or a bipolar shape. As a material of the electrostatic electrode 13, for example, tungsten or the like may be used.

The adhesive layer 15 is provided to fix the base body 12 onto the base plate 16. As the adhesive layer 15, for example, silicon adhesive or the like having good heat conductivity may be used. Additionally, in order to fix the base body 12 onto the base plate 16, indium metal or the like may be used instead of the adhesive layer 15 or a structure may be used in which the base body 12 is mechanically fixed onto the base plate 16.

The base plate 16 is used to support the electrostatic chuck 11. As a material of the base plate 16, for example, Al or the like may be used. The base plate 16 is provided with a water path 14 and a heater (not shown) in addition to the above-described gas introduction portion 18a formed through the base plate 16 for introducing the inert gas into the annular gas path 18 in the base body 12, and the temperature of the substrate 17 is controlled in terms of the base body 12. The water path 14 includes a cooling water introduction portion 14a and a cooling water discharge portion 14b formed in the lower portion of the base plate 16. The cooling water introduction portion 14a and the cooling water discharge portion 14b are connected to a cooling water control device (not shown) provided in the outside of the substrate temperature adjusting-fixing device 10.

The cooling water control device (not shown) circulates a cooling water so as to cool the base plate 16 in such a manner that the cooling water is introduced from the cooling water introduction portion 14a into the water path 14 and is discharged from the cooling water discharge portion 14b, thereby cooling the base body 12 via the adhesive layer 15. The heater (not shown) is heated upon being applied with a voltage and heats the base body 12 via the adhesive layer 15.

Unlike the substrate temperature adjusting-fixing device 100 according to the conventional art, the substrate temperature adjusting-fixing device 10 according to the first embodiment of the invention has a configuration in which the annular gas path 18 is not formed in the inside of the base plate 16 made from metals such as Al, thereby preventing a case in which a structure of the base plate 16 becomes complex. Accordingly, since it is not necessary to perform a process using an electron beam welding to the base plate 16, the base plate 16 is not expensive, thereby realizing a decrease in manufacture cost of the substrate temperature adjusting-fixing device 10.

Likewise, the substrate temperature adjusting-fixing device 10 according to the first embodiment of the invention holds the substrate 17 in the upper surfaces of the plurality of protrusion portions 12c and the outer peripheral seal ring 12b formed in the upper surface 12a of the base body 12 of the electrostatic chuck 11 in an adsorption state, and controls the temperature of the substrate 17 in terms of the heater (not shown) or the water path 14 embedded in the base plate 16. Additionally, with a configuration in which the annular gas path 18 is formed in the inside of the base body 12 and the inert gas introduced into the annular gas path 18 is filled in the gas filling portion 19, the heat conductivity between the base body 12 and the substrate 17 is improved and the temperature uniformity of the substrate 17 is realized.

In the substrate temperature adjusting-fixing device 10, if a thickness t₁ of the base body 12 is thin when the substrate 17 is held in the upper surfaces of the outer peripheral seal ring 12b and the plurality of protrusion portions 12c in an adsorption state, since a distance between the substrate 17 and the end surface of the base plate 16 becomes short, arcing (abnormal electrical discharge) may be easily generated. As a voltage applied to the electrostatic electrode 13 becomes larger, the arcing is more frequently generated. Additionally, if the thickness t₁ of the base body 12 is thin when the substrate 17 is held in the upper surfaces of the outer peripheral seal ring 12b and the plurality of protrusion portions 12c in an adsorption state, since a distance between the substrate 17 and the end surface of the adhesive layer 15 becomes short, plasma is caught inward and the adhesive layer 15 deteriorates, thereby causing a problem in which the inert gas leaks to the outside of the gas filling portion 19.

Since the substrate temperature adjusting-fixing device 10 according to the first embodiment of the invention has a configuration in which the thickness t₁ of the base body 12 is set to 2 mm or more, a distance between the substrate 17 and the end surfaces of the base plate 16 and the adhesive layer 15 becomes long, thereby preventing the occurrence of the arcing or the deterioration of the adhesive layer 15 due to the plasma caught inward.

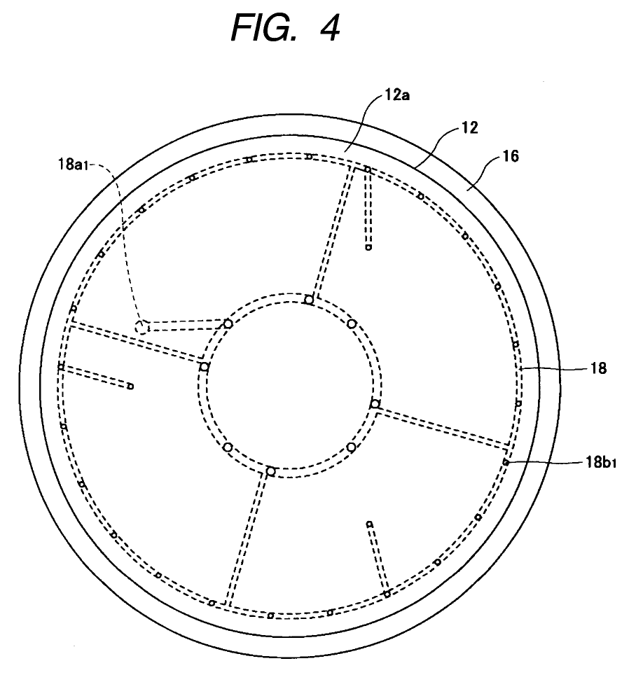

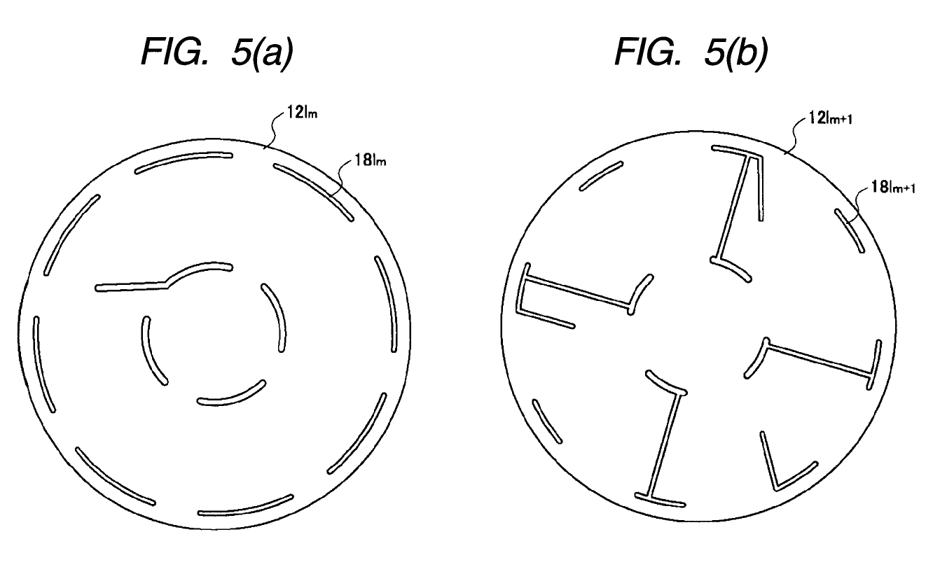

The annular gas path 18 provided in the inside of the base body 12 will be described in more detail with reference to FIGS. 4 and 5. FIG. 4 is a schematic top view showing a schematic path of the annular gas path 18. In the same drawing, the same reference numerals are given to the same components as those of FIG. 3, and the description thereof will be omitted. Additionally, since FIG. 3 simply shows the substrate temperature adjusting-fixing device 10, some parts shown in FIG. 3 may not be identical with those shown in FIG. 4.

In FIG. 4, the annular gas path 18 is embedded in the base body 12 and has a structure in which two types of large and small concentric annular portions are connected to each other at a plurality of positions in a top view. The annular gas path 18 is formed so as to be substantially in parallel to the upper surface 12a of the base body 12. The sections of the two types of large and small concentric annular portions in a top view may be formed into any shape such as a circular shape, an oval shape, or a polygonal shape. Additionally, the two types of large and small concentric annular portions in a top view may be formed to have the same thickness or different thicknesses.

The annular gas path 18 may have a structure having one type of annular portion in a top view or a structure in which three types or more of adjacent concentric annular portions are connected to each other at a plurality of positions in a top view. Here, the plurality of annular portions forming the annular gas path 18 may not be necessarily formed into a concentric shape, but may be formed into, for example, a polygonal shape in a top view instead of an annular shape in a top view. Alternatively, with a structure in which two types or more of independent annular portions are provided while not being connected to each other in a top view and a gas introduction portion is provided while communicating with each annular portion in a top view, a pressure or the like of the inert gas introduced into each annular portion in a top view may be independently controlled.

The gas introduction portion 18a is formed from the annular gas path 18 toward the lower surface 16b of the base plate 16 and is terminated in the opening 18a₁ of the lower surface 16b of the base plate 16 so as to be formed through the adhesive layer 15 and the base plate 16 while communicating with the annular gas path 18. In FIG. 4, the opening 18a₁ is provided only at one position of the lower surface 16b of the base plate 16.

A plurality of the gas discharge portions 18b is formed from the annular gas path 18 toward the upper surface 12a of the base body 12 and is terminated in a plurality of openings 18b₁ of the upper surface 12a of the base body 12 while communicating with the annular gas path 18. In FIG. 4, the openings 18b₁ are provided at twenty seven positions corresponding to the gas filling portion 19 of the upper surface 12a of the base body 12.

FIG. 5 is a schematic top view showing a gas path pattern in each layer of the base body 12. In FIG. 5(a), 121ₘ denotes a green sheet corresponding to an m-th layer and 181ₘ denotes a gas path pattern formed in the m-th layer, 121ₘ. In FIG. 5(b), 121ₘ₊₁ denotes a green sheet corresponding to an m+1-th layer and 181ₘ₊₁ denotes a gas path pattern formed in the m+1-th layer, 121ₘ₊₁ (1<m<n; m and n are positive numbers). The annular gas path 18 is formed in the inside of the base body 12 in such a manner that the predetermined gas path patterns 181ₘ and 181ₘ₊₁ shown in FIGS. 5(a) and 5(b) are formed in advance in the green sheet 121ₘ corresponding to the m-th layer and the green sheet 121ₘ₊₁ corresponding to the m+1-th layer, which are a part of n layers of green sheets forming the base body 12, and are laminated.

Specifically, first, two sheets of green sheets 121ₘ and 121ₘ₊₁ respectively corresponding to the m-th layer and m+1-th layer of the base body 12 are made by laminating n layers of green sheets 121₁ to 121ₙ. Subsequently, the predetermined gas path patterns 181ₘ and 181ₘ₊₁ shown in FIGS. 5(a) and 5(b) are respectively formed in two sheets of green sheets 121ₘ and 121ₘ₊₁ respectively corresponding to the m-th layer and m+1-th layer.

Subsequently, two sheets of green sheets having the predetermined gas path patterns 181ₘ and 181ₘ₊₁ formed therein are laminated together with green sheets corresponding to other layers, and n layers of green sheets 121₁ to 121ₙ are thermally compressed. Subsequently, the laminated structure in which n layers of green sheets 121₁ to 121ₙ are thermally compressed are burned and sintered. Accordingly, the base body 12 is made in which the annular gas path 18 is formed in a part where the 121ₘ corresponding to the m-th layer and the 121ₘ₊₁ corresponding to the m+1-th layer are laminated. Additionally, the annular gas path 18 may be formed in such a manner that the predetermined gas path patterns are formed in two sheets or more of green sheets and are laminated.

Likewise, it is possible to easily form the annular gas path 18 in the inside of the base body 12 in such a manner that the plurality of green sheets having the predetermined gas path patterns formed therein are laminated, burned, and sintered. At this time, unlike a case in which the annular gas path 18 is formed in the inside of the base plate 16 made from metals such as Al, it is not necessary to use an electron beam welding or the like.

With the substrate temperature adjusting-fixing device 10 according to the first embodiment of the invention, since the annular gas path 18 is embedded in the base body 12, the structure of the base plate 16 is not complex and the base plate 16 needs not to be treated by an electron beam welding or the like. Accordingly, it is possible to prevent an increase in cost of the base plate 16 and thus to realize a decrease in manufacture cost of the substrate temperature adjusting-fixing device 10.

Additionally, since the annular gas path 18 is embedded in the base body 12 and is separated from the heater and the water path 14 embedded in the base plate 16, it is possible to prevent the temperature of the inert gas introduced into the annular gas path 18 from being influenced by the temperature of the base plate 16 and thus to realize the temperature uniformity of the substrate 17.

### Second Embodiment

In the substrate temperature adjusting-fixing device 10 according to the first embodiment of the invention, for example, in case of the substrate 17 made from silicon wafer, an RF (high frequency) may be applied to the base plate 16 when the substrate 17 as the silicon wafer is subjected to etching. When the RF (high frequency) is applied to the base plate 16, a potential difference is generated in the gas path 18, thereby generating the arcing (abnormal electrical discharge) in the gas path 18 in some cases in the gas path 18.

In order to prevent the arcing from being generated in the gas path 18, it is efficient to perform a treatment in which a potential difference is hardly generated in the gas path 18. In the second embodiment, in order to prevent the arcing from being generated in the gas path 18, there is shown an example of the substrate temperature adjusting-fixing device having the electrostatic chuck subjected to the treatment in which the potential difference is hardly generated.

Additionally, in the substrate temperature adjusting-fixing device 100 according to the conventional art in which the gas path 108 is embedded in the base plate 106, since the base plate 106 is made from metals such as Al and the potential difference is hardly generated in the gas path 108, thereby not causing the arcing to be generated in the gas path 108.

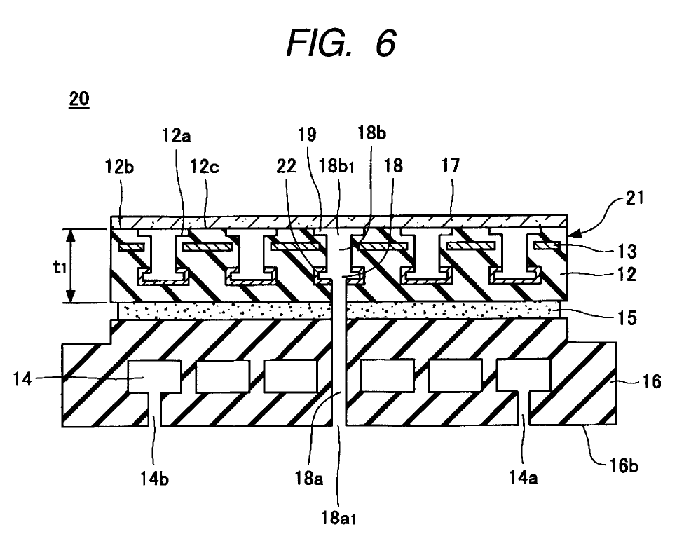

FIG. 6 is a cross sectional view showing a simplified example of a substrate temperature adjusting-fixing device 20 according to the second embodiment of the invention. In the same drawing, the same reference numerals are given to the same components as those of the substrate temperature adjusting-fixing device 10 according to the first embodiment of the invention, and the description thereof will be omitted. As shown in FIG. 6, the substrate temperature adjusting-fixing device 20 includes an electrostatic chuck 21, the adhesive layer 15, and the base plate 16.

The electrostatic chuck 21 is the coulombic-force electrostatic chuck having the base body 12 and the electrostatic electrode 13. The base body 12 is the dielectric and is fixed onto the base plate 16 via the adhesive layer 15. As the base body 12, for example, ceramics mainly composed of Al₂O₃ or AlN may be used. The inside of the base body 12 is provided with an annular gas path 18 and a gas discharge portion 18b for discharging inert gas introduced into the annular gas path 18. Unlike the substrate temperature adjusting-fixing device 10, a conductive layer 22 is formed in the inner wall of the annular gas path 18.

The conductive layer 22 is a layer formed of a conductive material formed in the inner wall of the annular gas path 18. As a material of the conductive layer 22, for example, tungsten or the like may be used, but all conductive materials may be used. A thickness of the conductive layer 22 is, for example, 10 μm.

As described in the first embodiment of the invention, it is possible to easily form the annular gas path 18 in the inside of the base body 12 in such a manner that the plurality of green sheets having the predetermined gas path patterns formed therein are laminated, burned, and sintered. At this time, it is possible to easily form the annular gas path 18 having the conductive layer 22 formed in the inner wall thereof in the inside of the base body 12 in such a manner that the green sheets having a conductive paste containing tungsten and the like printed thereon are laminated, burned, and sintered on a portion corresponding to the inner wall of the annular gas path 18.

With the substrate temperature adjusting-fixing device 20 according to the second embodiment of the invention, since the annular gas path 18 is embedded in the base body 12 like the substrate temperature adjusting-fixing device 10 according to the first embodiment of the invention, the structure of the base plate 16 is not complex and the base plate 16 needs not to be treated by the electron beam welding or the like. Accordingly, it is possible to prevent the increase in cost of the base plate 16 and thus to realize the decrease in manufacture cost of the substrate temperature adjusting-fixing device 20.

Additionally, since the annular gas path 18 is embedded in the base body 12 and is separated from the heater or the water path 14 embedded in the base plate 16, it is possible to prevent the temperature of the inert gas introduced into the annular gas path 18 from being influenced by the temperature of the base plate 16 and thus to realize the temperature uniformity of the substrate 17.

Additionally, since the conductive layer 22 is formed in the inner wall of the annular gas path 18, the potential difference is hardly generated in the gas path 18. Accordingly, it is possible to prevent the arcing from being generated in the annular gas path 18.

### Third Embodiment

In the third embodiment of the invention, in order to prevent the arcing from being generated in the gas path 18, there is shown another example of the substrate temperature adjusting-fixing device having the electrostatic chuck subjected to the treatment in which the potential difference is hardly generated in the gas path 18.

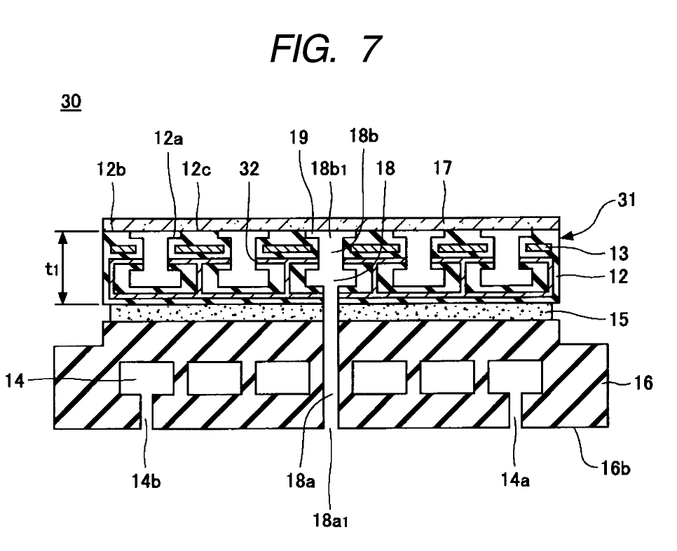

FIG. 7 is a cross sectional view showing a simplified example of a substrate temperature adjusting-fixing device 30 according to the third embodiment of the invention. In the same drawing, the same reference numerals are given to the same components as those of the substrate temperature adjusting-fixing device 10 according to the first embodiment of the invention, and the description thereof will be omitted. As shown in FIG. 7, the substrate temperature adjusting-fixing device 30 includes an electrostatic chuck 31, the adhesive layer 15, and the base plate 16.

The electrostatic chuck 31 is the coulombic-force electrostatic chuck having the base body 12 and the electrostatic electrode 13. The base body 12 is the dielectric and is fixed onto the base plate 16 via the adhesive layer 15. As the base body 12, for example, ceramics mainly composed of Al₂O₃ or AlN may be used. The inside of the base body 12 is provided with an annular gas path 18 and a gas discharge portion 18b for discharging inert gas introduced into the annular gas path 18. Unlike the substrate temperature adjusting-fixing device 10, a conductive layer 22 is formed in the upper, lower, left, and right portions of the annular gas path 18 of the inside of the base body 12.

The conductive layer 32 is a layer formed of the conductive material formed in the upper, lower, left, and right portions of the annular gas path 18 of the inside of the base body 12. As a material of the conductive layer 32, for example, tungsten or the like may be used, but all conductive materials may be used. A thickness of the conductive layer 32 is, for example, 10 μm.

As described in the first embodiment of the invention, it is possible to easily form the annular gas path 18 in the inside of the base body 12 in such a manner that the plurality of green sheets having the predetermined gas path patterns formed therein are laminated, burned, and sintered. At this time, it is possible to easily form the annular gas path 18 having the conductive layer 32 formed in the upper, lower, left, and right portions thereof in the inside of the base body 12 in such a manner that the green sheets having the conductive paste containing tungsten and the like printed thereon are laminated, burned, and sintered on a portion corresponding to the upper, lower, left, and right portions of the annular gas path 18.

With the substrate temperature adjusting-fixing device 30 according to the third embodiment of the invention, since the annular gas path 18 is embedded in the base body 12 like the substrate temperature adjusting-fixing device 10 according to the first embodiment of the invention, the structure of the base plate 16 is not complex and the base plate 16 needs not to be treated by the electron beam welding or the like. Accordingly, it is possible to prevent the increase in cost of the base plate 16 and thus to realize the decrease in manufacture cost of the substrate temperature adjusting-fixing device 30.

Additionally, since the annular gas path 18 is embedded in the base body 12 and is separated from the heater and the water path 14 embedded in the base plate 16, it is possible to prevent the temperature of the inert gas introduced into the annular gas path 18 from being influenced by the temperature of the base plate 16 and thus to realize the temperature uniformity of the substrate 17.

Additionally, since the conductive layer 32 is formed in the upper, lower, left, and right portions of the annular gas path 18, the potential difference is hardly generated in the gas path 18. Accordingly, it is possible to prevent the arcing from being generated in the annular gas path 18.

### Fourth Embodiment

In the fourth embodiment of the invention, in order to prevent the arcing from being generated in the gas path 18, there is shown still another example of the substrate temperature adjusting-fixing device having the electrostatic chuck subjected to the treatment in which the potential difference is hardly generated.

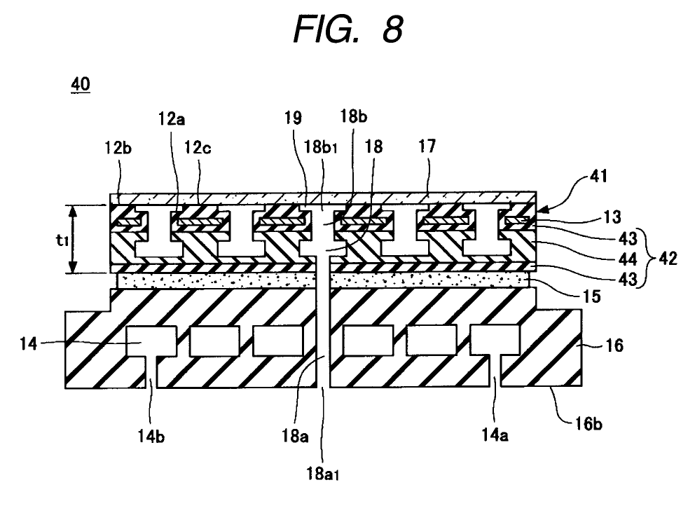

FIG. 8 is a cross sectional view showing a simplified example of a substrate temperature adjusting-fixing device 40 according to the fourth embodiment of the invention. In the same drawing, the same reference numerals are given to the same components as those of the substrate temperature adjusting-fixing device 40 according to the fourth embodiment of the invention, and the description thereof will be omitted. As shown in FIG. 8, the substrate temperature adjusting-fixing device 40 includes an electrostatic chuck 41, the adhesive layer 15, and the base plate 16.

The electrostatic chuck 41 is the coulombic-force electrostatic chuck having a base body 42 and the electrostatic electrode 13. The base body 42 is the dielectric and is fixed onto the base plate 16 via the adhesive layer 15. As the base body 42, for example, ceramics mainly composed of Al₂O₃ or AlN may be used.

The base body 42 includes a first region 43 having a predetermined volume resistance rate and a second region 44 having a lower volume resistance rate than that of the first region 43. The first region 43 is provided above and below the second region 44, and the annular gas path 18 is provided in the second region 44 having the lower volume resistance rate than that of the first region 43.

The volume resistance rate of the first region 43 may be set to be, for example, in the range of 10¹² to 10¹⁶ Ωm. The volume resistance rate of the second region 44 may be set to be, for example, not more than 10¹⁰ Ωm. As described above, as the base body 42, for example, ceramics mainly composed of Al₂O₃ or AlN may be used, but when ceramics forming the second region 44 contains, for example, conductive material such as Ti or Cr, it is possible to reduce the volume resistance rate.

As described in the first embodiment of the invention, it is possible to easily form the annular gas path 18 in the inside of the base body 42 in such a manner that the plurality of green sheets having the predetermined gas path patterns formed therein are laminated, burned, and sintered. At this time, it is possible to easily form the base body 42 which has the first region 43 having the predetermined volume resistance rate and the second region 44 having the lower volume resistance rate than that of the first region 43 and in which the annular gas path 18 is formed in the second region 44 in such a manner that the predetermined sheets of green sheets including the green sheets having the predetermined gas path patterns corresponding to the annular gas path 18 formed therein have the lower volume resistance rate than those of the green sheets laminated thereabove or therebelow and are laminated, burned, and sintered.

With the substrate temperature adjusting-fixing device 40 according to the fourth embodiment of the invention, since the annular gas path 18 is embedded in the base body 42 like the substrate temperature adjusting-fixing device 10 according to the first embodiment of the invention, the structure of the base plate 16 is not complex and the base plate 16 needs not to be treated by the electron beam welding or the like. Accordingly, it is possible to prevent the increase in cost of the base plate 16 and thus to realize the decrease in manufacture cost of the substrate temperature adjusting-fixing device 40.

Additionally, since the annular gas path 18 is embedded in the base body 42 and is separated from the heater and the water path 14 embedded in the base plate 16, it is possible to prevent the temperature of the inert gas introduced into the annular gas path 18 from being influenced by the temperature of the base plate 16 and thus to realize the temperature uniformity of the substrate 17.

Additionally, since the first region 43 having the predetermined volume resistance rate and the second region 44 having the lower volume resistance rate than that of the first region 43 are formed and the annular gas path 18 is provided in the second region 44, the potential difference is hardly generated in the gas path 18. Accordingly, it is possible to prevent the arcing from being generated in the inside of the annular gas path 18.

### Fifth Embodiment

In the fifth embodiment of the invention, in order to prevent the arcing from being generated in the gas path 18, there is shown still another example of the substrate temperature adjusting-fixing device having the electrostatic chuck subjected to the treatment in which the potential difference is hardly generated. Additionally, the substrate temperature adjusting-fixing device 50 according to the fifth embodiment of the invention is a modified example of the substrate temperature adjusting-fixing device according to the fourth embodiment of the invention.

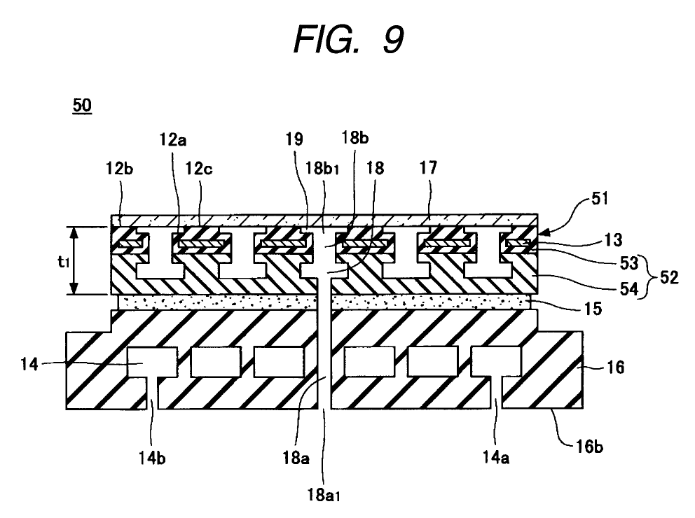

FIG. 9 is a cross sectional view showing a simplified example of a substrate temperature adjusting-fixing device 50 according to the fifth embodiment of the invention. In the same drawing, the same reference numerals are given to the same components as those of the substrate temperature adjusting-fixing device 10 according to the first embodiment of the invention, and the description thereof will be omitted. As shown in FIG. 9, the substrate temperature adjusting-fixing device 50 includes an electrostatic chuck 51, the adhesive layer 15, and the base plate 16.

The electrostatic chuck 51 is the coulombic-force electrostatic chuck having a base body 52 and the electrostatic electrode 13. The base body 52 is the dielectric and is fixed onto the base plate 16 via the adhesive layer 15. As the base body 52, for example, ceramics mainly composed of Al₂O₃ or AlN may be used.

The base body 52 includes a first region 53 having a predetermined volume resistance rate and a second region 54 having a lower volume resistance rate than that of the first region 53. The first region 53 is provided in the second region 54, and the annular gas path 18 is provided in the second region 54 having the lower volume resistance rate than that of the first region 53.

The volume resistance rate of the first region 53 may be set to be, for example, in the range of 10¹² to 10¹⁶ Ωm. The volume resistance rate of the second region 54 may be set to be, for example, not more than 10¹⁰ Ωm. As described above, as the base body 52, for example, ceramics mainly composed of Al₂O₃ or AlN may be used, but when ceramics forming the second region 54 contains, for example, conductive material such as Ti or Cr, it is possible to reduce the volume resistance rate.

As described in the first embodiment of the invention, it is possible to easily form the annular gas path 18 in the inside of the base body 52 in such a manner that the plurality of green sheets having the predetermined gas path patterns formed therein are laminated, burned, and sintered. At this time, it is possible to easily form the base body 52 which has the first region 53 having the predetermined volume resistance rate and the second region 54 having the lower volume resistance rate than that of the first region 53 and in which the annular gas path 18 is formed in the second region 54 in such a manner that a predetermined sheet of green sheets including the green sheets having the predetermined gas path patterns corresponding to the annular gas path 18 formed therein have the lower volume resistance rate than those of the green sheets laminated thereabove and are laminated, burned, and sintered.

With the substrate temperature adjusting-fixing device 50 according to the fifth embodiment of the invention, since the annular gas path 18 is embedded in the base body 52 like the substrate temperature adjusting-fixing device 10 according to the first embodiment of the invention, the structure of the base plate 16 is not complex and the base plate 16 needs not to be treated by the electron beam welding or the like. Accordingly, it is possible to prevent the increase in cost of the base plate 16 and thus to realize the decrease in manufacture cost of the substrate temperature adjusting-fixing device 50.

Additionally, since the annular gas path 18 is embedded in the base body 52 and is separated from the heater and the water path 14 embedded in the base plate 16, it is possible to prevent the temperature of the inert gas introduced into the annular gas path 18 from being influenced by the temperature of the base plate 16 and thus to realize the temperature uniformity of the substrate 17.

Additionally, since the first region 53 having the predetermined volume resistance rate and the second region 54 having the lower volume resistance rate than that of the first region 53 are formed and the annular gas path 18 is provided in the second region 54, the potential difference is hardly generated in the gas path 18. Accordingly, it is possible to prevent the arcing from being generated in the inside of the annular gas path 18.

While the exemplary embodiments of the invention have been described in detail, the invention is not limited to the above-described embodiments, but various modifications and substitutions of the above-described embodiments can be made without departing from the scope of the invention.

For example, the second embodiment may be used in combination with the third embodiment or the fourth embodiment or other combinations may be used.

What is claimed is:

1. An electrostatic chuck comprising:
a base body, and
an electrostatic electrode embedded in the base body, wherein
an adsorption object is placed on an upper surface of a base body,
an inert gas of which a pressure is adjusted is filled into a space formed between the upper surface of the base body and a lower surface of the adsorption object,
the base body is provided with a gas discharge portion embedded therein for discharging the inert gas to the space and a gas path embedded therein, communicating with the gas discharge portion, for introducing the inert gas to the gas discharge portion.

2. The electrostatic chuck according to claim 1, wherein
the gas path is formed into an annular shape in a top view and has a structure in which a plurality of annular portions are connected to one another at a plurality of positions in a top view.

3. The electrostatic chuck according to claim 1, wherein
an inner wall of the gas path is provided with a layer formed of a conductive material.

4. The electrostatic chuck according to claim 1, wherein
upper, lower, left, and right portions of the gas path are provided with a layer formed of a conductive material.

5. The electrostatic chuck according to claim 1, wherein
the base body includes two or more regions having different volume resistance rates, and
the gas path is provided in the region having the lowest volume resistance rate.

6. The electrostatic chuck according to claim 5, wherein
the volume resistance rate of the region provided with the gas path is not more than 10¹⁰ Ωm.

7. A substrate temperature adjusting-fixing device comprising:
the electrostatic chuck according to claim 1, and
a base plate for supporting the electrostatic chuck.

8. The substrate temperature adjusting-fixing device according to claim 7, wherein
the base plate includes a gas introduction portion embedded therein to introduce the inert gas into the gas path embedded in the base body of the electrostatic chuck.

9. The substrate temperature adjusting-fixing device according to claim 8, wherein
the base plate further comprises:
a heater embedded therein to heat the electrostatic chuck, and
a water path embedded therein to cool the electrostatic chuck.
